(19) United States
(12) Patent Application Publication
(10) Pub. No.: US 2008/0217634 A1
(43) Pub. Date: Sep. 11, 2008

(54) VERTICAL LIGHT-EMITTING DIODE STRUCTURE WITH OMNI-DIRECTIONAL REFLECTOR

(76) Inventors: Wen-Huang Liu, Guan-Xi Town (TW); Yuan-Hsiao Chang, Daya Township (TW); Li-Wei Shan, Taipei (TW)

Correspondence Address: PATTERSON & SHERIDAN, L.L.P., 3040 POST OAK BOULEVARD, SUITE 1500, HOUSTON, TX, 77056, US

(21) Appl. No.: 11/682,780

(22) Filed: Mar. 6, 2007

(51) Int. Cl. H01L 33/00

(52) U.S. Cl. 257/98; 257/E33.072

(57) ABSTRACT

A vertical light-emitting diode (VLED) structure with an omni-directional reflector (ODR) that may offer increased light extraction and greater luminous efficiency when compared to conventional VLEDs is provided.

### BACKGROUND OF THE INVENTION

1. Field of the Invention

Embodiments of the present invention generally relate to the field of light-emitting diode (LED) technology and, more particularly, to a vertical light-emitting diode (VLED) structure.

2. Description of the Related Art

Light-emitting diodes (LEDs) have been around for several decades, and research and development efforts are constantly being directed towards improving their luminous efficiency, thereby increasing the number of possible applications.

A major limiting factor on improving luminous efficiency has been the inability of conventional LEDs to emit all of the light that is generated by their active layer. When an LED is forward biased, light emitting from its active layer (in all directions) reaches the emitting surfaces at many different angles. Typical semiconductor materials have a high index of refraction (n≈2.2-3.8) compared to ambient air (n=1.0) or encapsulating epoxy (n≈1.5). According to Snell's Law, light traveling from a region having a high index of refraction to a region with a low index of refraction that is within a certain critical angle (relative to the surface normal direction) will cross to the lower index region. Light that reaches the surface beyond the critical angle will not cross but will experience total internal reflection (TIR). In the case of an LED, the TIR light can continue to be reflected within the LED until it is absorbed, often by the substrate on which the epitaxial layers of the LED were deposited. Because of this phenomenon, much of the light generated by the active layer of a conventional LED is never emitted, thereby degrading its efficiency.

Several techniques have been implemented to increase the light extraction from an LED including metal reflectors and distributed Bragg reflectors (DBRs). A metal reflector is a layer of reflective metal, such as silver (Ag) or aluminum (Al), that may be formed in the LED structure during fabrication and disposed on a side of the active layer opposite the desired light emission surface. With metal reflectors, light emitting from the active layer may be emitted from the LED, may be reflected by the emitting surface according to Snell's Law for internal reflection, or may be reflected by the metal reflector towards the emitting surface. The internally reflected light that is not absorbed may be reflected by the metal reflector for another chance at being emitted from the LED, provided the angle relative to the surface is below the critical angle. However, the reflectivity of metals used in the metal reflector is typically limited to ˜95% in the visible wavelength region, and thus, the LED light extraction is physically limited (J. K. Kim, J. Q. Xi, and E. F. Schubert. “Omni-Directional Reflectors for Light-Emitting Diodes.” Proc. Of SPIE. Vol. 6134. 2006).

DBRs are periodic structures with a unit cell of two dielectric layers having different refractive indices and quarter-wavelength thicknesses. However, the DBR reflectivity depends on the angle of incidence such that the stop band shifts toward shorter wavelengths for increasing incidence angles without changing its spectral width. As a result, at oblique angles of incidence, a DBR becomes transparent, which results in optical losses as light may be absorbed by the substrate or other bonded structure rather than being reflected by the DBR.

Accordingly, what is needed is an LED structure with increased light extraction and greater luminous efficiency.

### SUMMARY OF THE INVENTION

Embodiments of the present invention generally provide vertical light-emitting diode (VLED) structures that may provide increased light extraction and greater luminous efficiency when compared to conventional VLEDs.

One embodiment of the present invention provides a light-emitting diode (LED) device. The LED device generally includes a metal substrate, a reflective layer disposed above the metal substrate, a conductive transparent layer disposed above the reflective layer, and an LED stack disposed above the conductive transparent layer.

Another embodiment of the present invention provides an LED device. The LED device generally includes a metal substrate, a reflective layer disposed above the metal substrate, a patterned transparent isolating layer disposed above the reflective layer, a conductive transparent layer disposed above the patterned transparent and isolating layer, a current blocking structure disposed within the conductive transparent layer, and an LED stack disposed above the conductive transparent layer.

Yet another embodiment of the present invention provides an LED device. The LED device generally includes a metal substrate, an omni-directional reflector (ODR) disposed above the metal substrate, wherein the ODR has a current blocking structure, and an LED stack disposed above the ODR.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional schematic representation of a vertical light-emitting diode (VLED) having an omni-directional reflector (ODR) comprising a conductive transparent layer and a reflective layer in accordance with an embodiment of the invention;

FIG. 2 is a cross-sectional schematic representation of the VLED in FIG. 1 where the n-doped surface layer has been roughened in an effort to increase light extraction in accordance with an embodiment of the invention;

FIG. 3 is a cross-sectional schematic representation of a VLED having an ODR comprising a conductive transparent layer, a patterned transparent isolating layer, and a reflective layer in accordance with an embodiment of the invention; and

FIG. 4 is a cross-sectional schematic representation of a VLED having an ODR comprising a conductive transparent layer with a current blocking structure, a patterned transparent isolating layer, and a reflective layer in accordance with an embodiment of the invention.

### DETAILED DESCRIPTION

Embodiments of the present invention provide a vertical light-emitting diode (VLED) structure that may provide increased light extraction and greater luminous efficiency when compared to conventional VLEDs.

### An Exemplary Led Structure

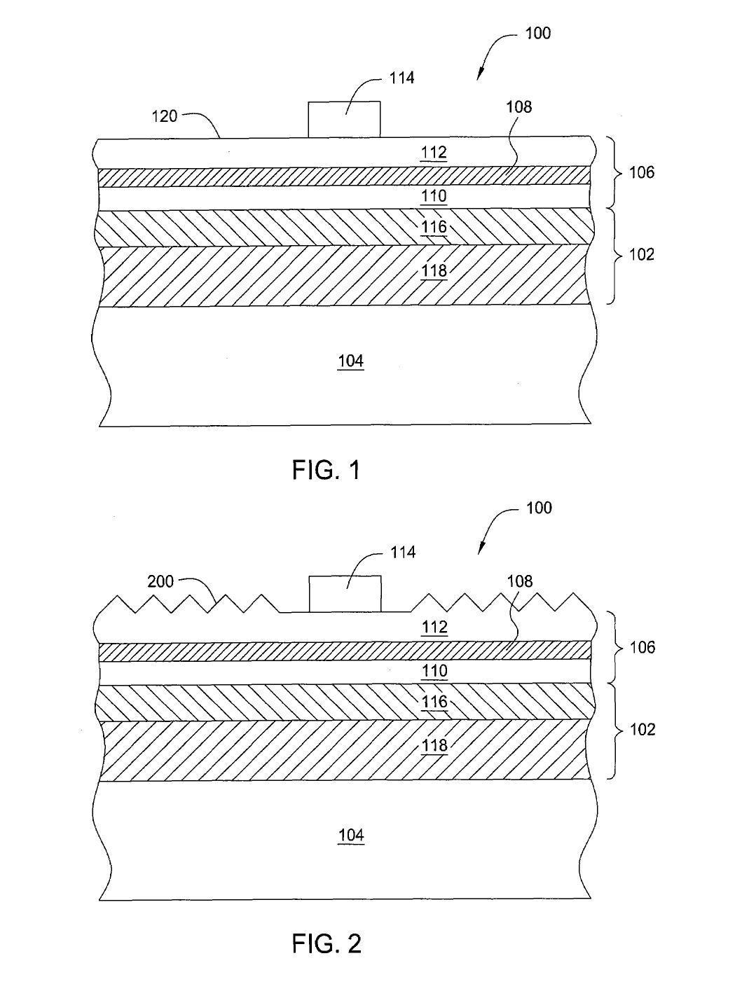

FIG. 1 illustrates a VLED structure 100 that may incorporate an omni-directional reflector (ODR) 102 in an effort to significantly increase light extraction when compared to conventional light-emitting diodes (LEDs). Able to reflect light in all directions, the ODR 102 may have high reflectivity and a wide stop band, thereby leading to greater LED light extraction than achievable with metal reflectors and distributed Bragg reflectors (DBRs).

The VLED structure 100 may comprise a metal substrate 104 for electrical and thermal conductivity deposited above the ODR 102 during fabrication of the VLED structure. Typically having a thickness between 10 μm and 400 μm, the metal substrate 104 may be composed of a single layer or multiple layers of any suitable metal or metal alloy, such as Cu, Ni, Ag, Au, Al, Cu—Co, Ni—Co, Cu—W, Cu—Mo, Ni/Cu, or Ni/Cu—Mo. The individual layers of a multilayer metal substrate may be composed of different metals or metal alloys and may possess different thicknesses. The metal substrate 104 may be deposited by any suitable deposition technique, such as electroplating, electroless plating, physical vapor deposition (PVD), chemical vapor deposition (CVD), or plasma enhanced CVD (PECVD).

An LED stack 106 may be disposed above the ODR 102. In FIG. 1, the LED stack 106 comprises a multiple quantum well (MQW) active layer 108 for emitting light sandwiched between a p-doped layer 110 and an n-doped layer 112. The layers 108, 110, 112 of the LED stack 106 may be composed of group III-group V semiconductor compounds, such as AlₓGa_{y}In_{1-x-y}N, where x≦1 and y≦1. The operation of the LED stack 106 is well-known to those skilled in the art and, thus, will not be described herein.

A contact pad or electrode 114 may be disposed above the LED stack 106 for external connection so that the LED stack 106 may be forward biased and emit light. For some embodiments as shown in FIG. 1, the electrode 114 may be coupled to the n-doped layer 112. The electrode 114 may comprise any suitable electrically conductive material, such as Au, Cr/Au, Cr/Al, Cr/Al, Cr/Pt/Au, Cr/Ni/Au, Cr/Al/Pt/Au, Cr/Al/Ni/Au, Al, Ti/Al, Ti/Au, Ti/Al/Pt/Au, Ti/Al/Ni/Au, Ti/Al/Pt/Au, Al, Al/Pt/Au, Al/Pt/Al, Al/Ni/Au, Al/Ni/Al, Al/W/Al, Al/W/Au, Al/TaN/Al, Al/TaN/Au, Al/Mo/Au, and alloys thereof. The thickness of the electrode 114 may be about 0.1 to 50 μm.

For some embodiments, the ODR 102 may comprise a conductive transparent layer 116 and a reflective layer 118 as illustrated in FIG. 1. The reflective layer 118 may comprise any suitable material for light reflection and electrical conduction, such as metals or metal alloys of Al, Ag, Au, AgNi, Ni/Ag/Ni/Au, Ag/Ni/Au, Ag/Ti/Ni/Au, Ti/Al, or Ni/Al. The purpose of the reflective layer 118 may be to reflect light transmitted from the active layer 108 and light being internally reflected back towards the light-emitting surface 120. The reflective layer 118 may also provide a seed layer on which the layer(s) of the metal substrate 120 may be deposited during fabrication of the VLED structure 100.

The conductive transparent layer 116 may comprise any suitable material exhibiting electrical conductivity and light transmission, such as indium tin oxide (ITO), indium oxide, tin oxide, zinc oxide, magnesium oxide, nickel oxide, titanium nitride, ruthenium oxide (RuO₂), and tantalum nitride (TaN). Ranging in thickness from 1 to 1000 nm typically, the purpose of the conductive transparent layer 116 may be to reflect and refract the incident light transmitted from the active layer 108 and reflected from the reflective layer 118 at different angles in an effort to increase light extraction from the light-emitting surface 120. Another purpose of the conductive transparent layer 116 may be to allow for current to travel in the forward biased LED stack 106, such that the combination of the metal substrate 104 for external connection, the reflective metal layer 118, and the conductive transparent layer 116 forms a counterpart to the electrode 114, although with substantially greater thermal conductivity. The thickness of the conductive transparent layer 116 may be controlled during fabrication of the VLED structure 100 to approach the desired 100% reflectivity by the ODR 102.

For some embodiments, the light-emitting surface 120 of the LED stack 106 may be roughened or patterned according to any desired shape in an effort to further increase light extraction from the VLED structure 100. Altering the light-emitting surface 120 from a flat surface to a roughened surface 200 may provide for many different critical angles for light incident upon the surface, thereby leading to more chances for LED light extraction and less total internal reflection (TIR). In other words, the roughened surface 200 may refract and reflect light in a manner not predicted by Snell's law due to random interference effects.

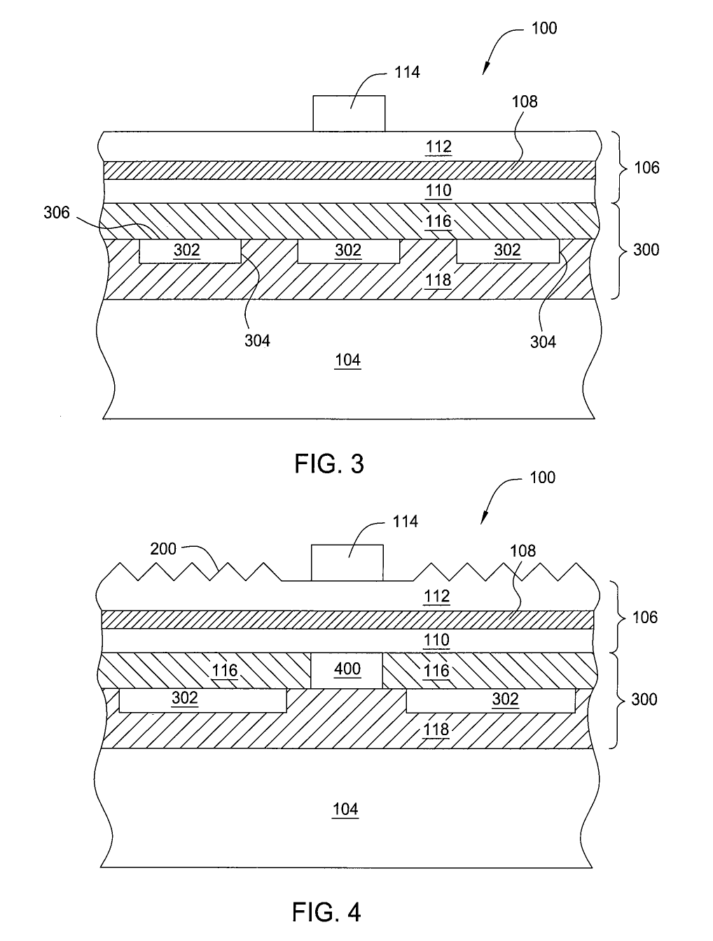

Referring now to FIG. 3, some embodiments of the VLED structure may provide an ODR 300 having a patterned transparent layer 302 interposed between the conductive transparent layer 116 and the reflective layer 118. Because the conductive transparent layer 116 may not be conducive to current spreading for some embodiments, the patterned transparent layer 302 may provide enhanced current spreading, thereby allowing for more uniform current flow through the reflective layer 118. The patterned transparent layer 302 may comprise any suitable material for permitting light transmission, such as SiO₂, Si₃N₄, TiO₂, Al₂O₃, HfO₂, ZnO, spin-on glass (SOG), or MgO. The thickness of the patterned transparent layer 302 may be in the range of about 5 to 10000 nm. For some embodiments, the patterned transparent layer 302 may cover more than 40% of the adjacent transparent conductive layer surface.

For some embodiments, the refractive indices of the conductive transparent layer 116 and the patterned transparent layer 302 may be slightly different in an effort to further alter the angles of light traversing the ODR 300, thereby potentially enhancing the reflectivity of the ODR 300. For other embodiments, the refractive indices may be substantially the same, especially if the two layers 116, 302 comprise the same material. Although not shown, the lateral surfaces 304 of the material comprising the patterned transparent layer 302 may be sloped for some embodiments in an effort to alter the angle of incidence at the interface 306 between the patterned transparent layer 302 and the conductive transparent layer 116 as reflected light may be further reflected off a lateral surface 304 of the patterned transparent layer 302 by the surrounding reflective layer 118.

During fabrication of the VLED structure, the constituents of the patterned transparent layer 302 may be formed above the conductive transparent layer 116 to create a substantially uniform layer. Then, a masking technique, for example, known to those skilled in the art may be used to remove material from the formed layer in an effort to achieve a desired pattern. Afterwards, the reflective layer 118 may be deposited above and fill in the spaces that are missing material from the patterned transparent layer 302.

Referring now to FIG. 4, the conductive transparent layer 116 may contain a current blocking structure 400 for some embodiments. The current blocking structure 400 may comprise any suitable non-conductive material, such as SiO₂, for preventing electric current from flowing through the LED stack 106 between the metal substrate 104 and the electrode 114 in the area where the structure 400 is positioned. For some embodiments as depicted in FIG. 4, the current blocking structure 400 may be positioned under the electrode 114. In such cases, the purpose of the current blocking structure 400 may be to limit the forward current in a region under the electrode 114 so that light is not emitted from a portion of the active layer 108 under the electrode 114 to simply be absorbed by the electrode 114. Thus, the current blocking structure 400 may serve to increase the luminous efficiency by preventing the VLED structure from wasting unnecessary current to emit from a portion of the active layer 108 to have it absorbed by the electrode 114 without being extracted.

While the foregoing is directed to embodiments of the present invention, other and further embodiments of the invention may be devised without departing from the basic scope thereof, and the scope thereof is determined by the claims that follow.

1. A light-emitting diode (LED) device comprising:
a metal substrate;
a reflective layer disposed above the metal substrate;
a conductive transparent layer disposed above the reflective layer; and
an LED stack disposed above the conductive transparent layer.

2. The LED device of claim 1, wherein the conductive transparent layer comprises at least one of indium tin oxide (ITO), indium oxide, tin oxide, zinc oxide, magnesium oxide, nickel oxide, titanium nitride, ruthenium oxide (RuO₂), and tantalum nitride (TaN).

3. The LED device of claim 1, wherein the conductive transparent layer has a thickness of 1 to 1000 nm.

4. The LED device of claim 1, further comprising a current blocking structure disposed within the conductive transparent layer.

5. The LED device of claim 4, wherein the current blocking structure is positioned under an electrode disposed above the LED stack.

6. The LED device of claim 4, wherein the current blocking structure comprises SiO₂.

7. The LED device of claim 1, further comprising a patterned transparent layer interposed between the conductive transparent layer and the reflective layer.

8. The LED device of claim 7, wherein the patterned transparent layer comprises at least one of SiO₂, Si₃N₄, TiO₂, Al₂O₃, HfO₂, ZnO, spin-on glass (SOG), and MgO.

9. The LED device of claim 7, wherein the patterned transparent layer has a thickness of 5 to 10000 nm.

10. The LED device of claim 7, wherein the patterned transparent layer covers more than 40% of an adjacent surface of the transparent conductive layer.

11. The LED device of claim 1, wherein the metal substrate comprises a single layer or multiple layers.

12. The LED device of claim 1, wherein the metal substrate comprises at least one of Cu, Ni, Ag, Au, Al, Cu—Co, Ni—Co, Cu—W, Cu—Mo, Ni/Cu, Ni/Cu—Mo, and alloys thereof.

13. The LED device of claim 1, wherein the metal substrate has a thickness of 10 to 400 μm.

14. The LED device of claim 1, wherein the reflective layer comprises at least one of Al, Ag, Au, AgNi, Ni/Ag/Ni/Au, Ag/Ni/Au, Ag/Ti/Ni/Au, Ti/Al, Ni/Al, and alloys thereof.

15. The LED device of claim 1, wherein the LED stack comprises a p-doped layer disposed above the conductive transparent layer, an active layer for emitting light disposed above the p-doped layer, and an n-doped layer disposed above the active layer.

16. The LED device of claim 1, wherein a surface of the LED stack is roughened.

17. The LED device of claim 1, wherein the LED stack comprises AlₓGa_{y}In_{1-x-y}N, where x≦1 and y≦1.

18. A light-emitting diode (LED) device comprising:
a metal substrate;
a reflective layer disposed above the metal substrate;
a patterned transparent layer disposed above the reflective layer;
a conductive transparent layer disposed above the patterned transparent and isolating layer;
a current blocking structure disposed within the conductive transparent layer;
an LED stack disposed above the conductive transparent layer.

19. The LED device of claim 18, wherein the conductive transparent layer comprises at least one of indium tin oxide (ITO), indium oxide, tin oxide, zinc oxide, magnesium oxide, nickel oxide, titanium nitride, ruthenium oxide (RuO₂), and tantalum nitride (TaN).

20. The LED device of claim 18, wherein the conductive transparent layer has a thickness of 1 to 1000 nm.

21. The LED device of claim 18, wherein the current blocking structure is positioned under an electrode disposed above the LED stack.

22. The LED device of claim 18, wherein the current blocking structure comprises SiO₂.

23. The LED device of claim 18, wherein the patterned transparent layer comprises at least one of SiO₂, Si₃N₄, TiO₂, Al₂O₃, HfO₂, ZnO, spin-on glass (SOG), and MgO.

24. The LED device of claim 18, wherein a surface of the LED stack is roughened.

25. The LED device of claim 18, wherein the LED stack comprises AlₓGa_{y}In_{1-x-y}, where x≦1 and y≦1.

26. A light-emitting diode (LED) device comprising:
a metal substrate;
an omni-directional reflector (ODR) disposed above the metal substrate, wherein the ODR has a current blocking structure; and
an LED stack disposed above the ODR.

27. The LED device of claim 26, wherein the current blocking structure is positioned under an electrode disposed above the LED stack.

28. The LED device of claim 26, wherein the current blocking structure comprises SiO₂.

29. The LED device of claim 26, wherein the ODR comprises a reflective layer and a conductive transparent layer, the current blocking structure disposed in the conductive transparent layer.

30. The LED device of claim 29, further comprising a patterned transparent layer interposed between the reflective layer and the conductive transparent layer.

31. The LED device of claim 26, wherein a surface of the LED stack is roughened.

32. The LED device of claim 26, wherein the LED stack comprises AlₓGa_{y}In_{1-x-y}N, where x≦1 and y≦1.
